(19) United States
(12) Patent Application Publication
(10) Pub. No.: US 2025/0384910 A1
(43) Pub. Date: Dec. 18, 2025

(54) MAGNETIC MEMORY DEVICE

(71) Applicant: Samsung Electronics Co., Ltd., Suwon-si (KR)

(72) Inventors: Bo Young SEO, Suwon-si (KR); Shin Hee HAN, Suwon-si (KR); Ki Seok SUH, Suwon-si (KR); Gi Woong KWON, Suwon-si (KR); Hee Ho KIM, Suwon-si (KR)

(21) Appl. No.: 19/024,056

(22) Filed: Jan. 16, 2025

(30) Foreign Application Priority Data
Jun. 13, 2024 (KR) 10-2024-0076948

(51) Int. Cl. G11C 11/16; H10N 50/10; H10N 50/80

(52) U.S. Cl. CPC G11C 11/1657; G11C 11/1673; G11C 11/1675; H10N 50/10; H10N 50/80; G11C 11/1659

(57) ABSTRACT

A magnetic memory device includes a memory cell connected to a bit-line and a word-line and including a first magnetic tunnel junction element; and a second magnetic tunnel junction element and a metal word-line on the word-line, and electrically connected to the word-line.

### CROSS-REFERENCE TO RELATED APPLICATION

This application claims priority from Korean Patent Application No. 10-2024-0076948, filed on Jun. 13, 2024, in the Korean Intellectual Property Office, and all the benefits accruing therefrom under 35 U.S.C. 119, the content of which in its entirety is herein incorporated by reference.

### BACKGROUND

### Field

The present disclosure relates to a magnetic memory device.

### Description of Related Art

As an electronic device becomes faster and/or has lower power consumption, demand for faster operation and/or lower operating voltage of a semiconductor memory element included in the electric device is increasing. To meet these requirements, a magnetic memory element has been proposed as the semiconductor memory element. The magnetic memory element is attracting attention as a next-generation semiconductor memory element because the magnetic memory element may have characteristics, such as high-speed operation and/or non-volatility.

In general, the magnetic memory element may include a magnetic tunnel junction (MTJ) element. The MTJ element may include two magnetic materials and an insulating film sandwiched therebetween. A resistance value of the MTJ element may vary depending on magnetization directions of the two magnetic materials. For example, when the magnetization directions of the two magnetic materials are anti-parallel to each other, the MTJ element may have a large resistance value. When the magnetization directions of the two magnetic materials are parallel to each other, the MTJ element may have a small resistance value. Data may be programmed and read using a difference between the resistance values.

Further, for fast operation of the memory device, it may be desirable to lower a resistance of a word-line.

### SUMMARY

A technical purpose of the present disclosure is to provide a magnetic memory device including a word-line strap structure and with improved operating speed.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to some example embodiments, a magnetic memory device includes a memory cell connected to a bit-line and a word-line and including a first magnetic tunnel junction element; and a second magnetic tunnel junction element and a metal word-line on the word-line, and electrically connected to the word-line.

According to some example embodiments, a magnetic memory device includes a substrate including a sub-memory cell array and a dummy area; a gate line on the substrate; a first magnetic tunnel junction element on a portion of the gate line on the sub-memory cell array; a second magnetic tunnel junction element on a portion of the gate line on the dummy area; and a metal word-line on the gate line, wherein the portion of the gate line on the dummy area is electrically connected to the second magnetic tunnel junction element and the metal word-line.

According to some example embodiments, a magnetic memory device includes a substrate including a sub-memory cell array and a dummy area; a bit-line and a word-line on the substrate; a memory cell on the sub-memory cell array of the substrate, wherein the memory cell includes a first memory element connected to the bit-line, and a select transistor connected to the first memory element and having a gate connected to the word-line; a metal word-line on the word-line; and a second memory element on the dummy area of the substrate, wherein the word-line on the dummy area is electrically connected to the second memory element and the metal word-line.

Specific details of other embodiments are included in the detailed description and drawings.

### BRIEF DESCRIPTION OF DRAWINGS

The above and other aspects and features of the present disclosure will become more apparent by describing in detail some embodiments thereof with reference to the attached drawings, in which:

FIG. 1 is an example block diagram of a magnetic memory device according to some embodiments;

FIG. 2 is an example circuit diagram for illustrating the memory cell array of a magnetic memory device according to some embodiments;

FIG. 3 is an example layout diagram for illustrating a magnetic memory device according to some embodiments;

FIG. 4 is a cross-sectional view cut along A-A′ in FIG. 3;

FIG. 5 is a cross-sectional view cut along B-B′ in FIG. 3;

FIG. 6 is a cross-sectional view cut along C-C′ in FIG. 3;

FIG. 7 and FIG. 8 are example cross-sectional views for illustrating first and second magnetic tunnel junction elements of FIGS. 4 to 6; and

FIGS. 9 to 14 are diagrams for illustrating a magnetic memory device according to some embodiments.

### DETAILED DESCRIPTION

Hereinafter, example embodiments of the present disclosure will be described in more detail with reference to the attached drawings. The same reference numerals are used for the same components in the drawings, and duplicate descriptions for the same components are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

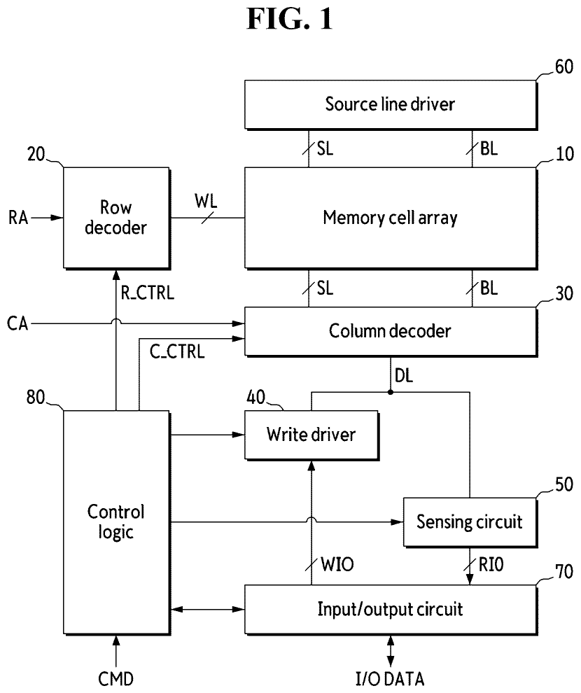

FIG. 1 is an example block diagram of a magnetic memory device according to some embodiments.

Referring to FIG. 1, a magnetic memory device according to some embodiments may include a memory cell array 10, a row decoder 20, a column decoder 30, a write driver 40, a sensing circuit 50, a source line driver 60, an input/output circuit 70, and a control logic 80.

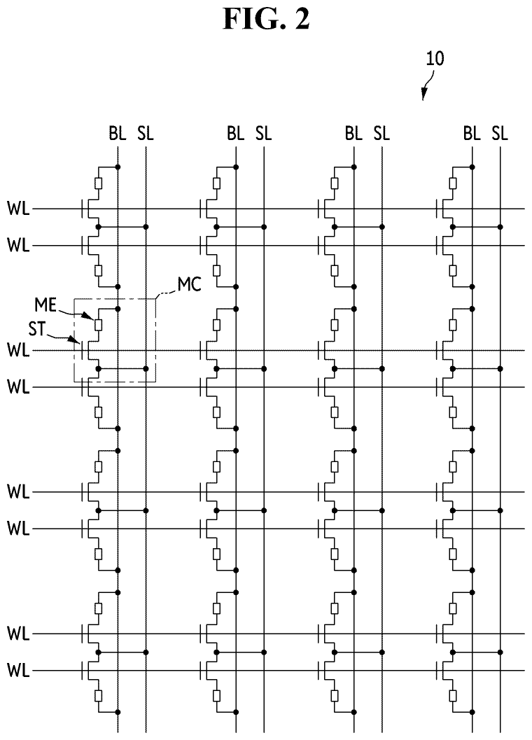

The memory cell array 10 may include a plurality of word-lines WL, a plurality of bit-lines BL, and a plurality of source lines SL. Memory cells (for example, memory cells MC in FIG. 2) may be electrically connected to points where the word-lines WL and the bit-line BL intersect each other, respectively. Each of the memory cells may be configured to store data therein. For example, the memory cell may include a variable resistance element in which a value of stored data is determined based on a resistance value, for example, a magnetic tunnel junction (MTJ) element.

For example, the memory cell may include Resistive RAM (ReRAM), Phase Change Random Access Memory (PRAM), Ferroelectric Random Access Memory (FRAM), etc. Alternatively, the memory cell may include Magnetic Random Access Memory (MRAM), such as Spin-Transfer Torque Magnetic Random Access Memory (STT-MRAM), Spin Torque Transfer Magnetization Switching RAM (Spin-RAM), and/or Spin Momentum Transfer RAM (SMT-RAM).

The row decoder 20 may select (or drive) a word-line WL electrically connected to a memory cell on which a read operation or a program operation is performed based on a row address RA and a row control signal R_CTRL. The row decoder 20 may provide a driving voltage input from the control logic 80 to the selected word-line.

The column decoder 30 may select a bit-line BL and/or a source line SL electrically connected to a memory cell on which a read operation or a program operation is performed based on a column address CA and a column control signal C_CTRL. The column decoder 30 may connect the selected bit-line BL and/or source line SL to the data line DL.

The write driver 40 may drive a program voltage (or write current) to store write data in the memory cell selected by the row decoder 20 and the column decoder 30 during a program operation. For example, during the program operation, the write driver 40 may control a voltage of the data line DL based on write data I/O DATA input from the input/output circuit 70 via a write input/output line WIO, such that the write data I/O DATA may be stored in the selected memory cell.

The sensing circuit 50 may detect a signal output via the data line DL and determine a value of data stored in the memory cell during a read operation. The sensing circuit 50 may be electrically connected to the column decoder 30 via the data line DL and may be electrically connected to the input/output circuit 70 via a read input/output line RIO. The sensing circuit 50 may input the sensed read data I/O DATA to the input/output circuit 70 via the read input/output line RIO.

The source line driver 60 may drive the source line SL at a specific voltage level under the control of the control logic 80. For example, the source line driver 60 may receive a voltage for driving the source line SL from the control logic 80.

The input/output circuit 70 may transmit the write data I/O DATA input from an external source to the write driver 40 and output the read data I/O DATA input from the sensing circuit 50 to an external element.

The control logic 80 may control all of the operations of the magnetic memory device. For example, the control logic 80 may control the row decoder 20, the column decoder 30, the write driver 40, the sensing circuit 50, the source line driver 60, the input/output circuit 70, etc. In one example, the control logic 180 may operate in response to a command CMD or control signals input from an external source. The command CMD may include a read command, a write command, etc.

FIG. 2 is an example circuit diagram for illustrating the memory cell array 10 of a magnetic memory device according to some embodiments.

The memory cell array 10 may include a plurality of memory cells MC, a plurality of word-lines WL, a plurality of bit-lines BL, and a plurality of source lines SL arranged in a matrix manner in rows and columns.

The memory cell MC may be connected to the word-line WL and the bit-line BL. The memory cell MC may include a select transistor ST and a memory element ME. A gate of the select transistor ST may be electrically connected to the word-line WL, a drain of the select transistor ST may be electrically connected to one end of the memory element ME, and a source of the select transistor ST may be electrically connected to the source line SL. The other end of the memory element ME may be electrically connected to the bit-line BL.

The memory element ME may include a variable resistance element whose value of stored data is determined based on a resistance value. For example, the memory element ME may include MRAM (Magneto-resistive RAM), STT-MRAM (Spin Transfer Torque MRAM), SOT-MRAM (Spin-Orbit Torque MRAM), PRAM (Phase-change RAM), and/or ReRAM (Resistive RAM), etc. Hereinafter, an example in which the memory element ME includes the STT-MRAM will be described. The memory element ME may include a magnetic tunnel junction element.

In some embodiments, the memory cell MC may have a structure in which one memory element ME is electrically connected to one select transistor ST. In some further embodiments, the memory cell MC may have a structure in which one memory element ME is electrically connected to two select transistors ST. In some embodiments, memory cells MC constituting one row may share one source line SL.

The select transistor ST may include, for example, a diode, a bipolar transistor, a fin field effect transistor, or a multi-bridge channel field effect transistor.

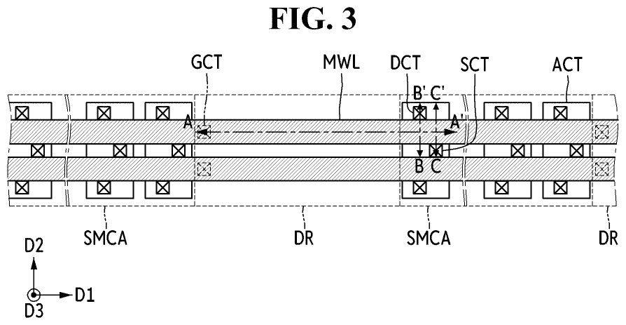

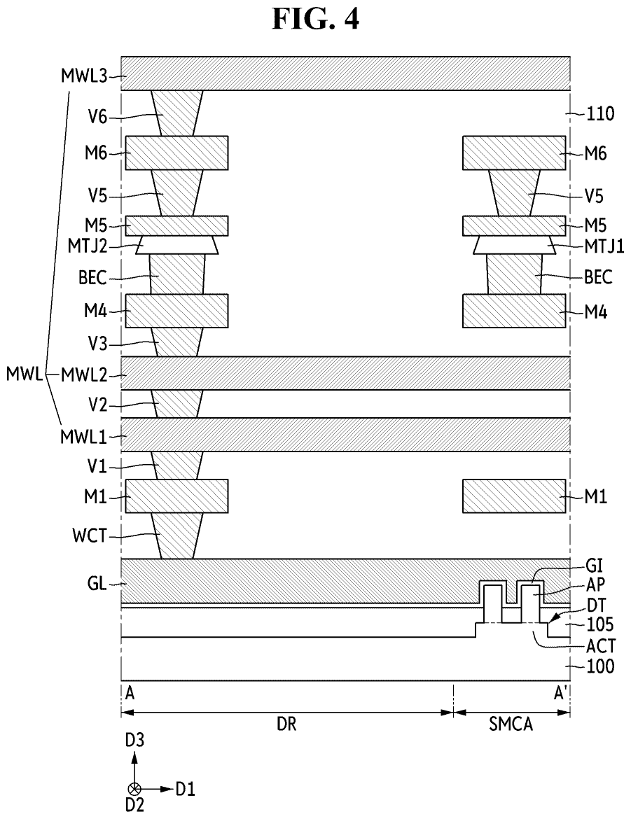

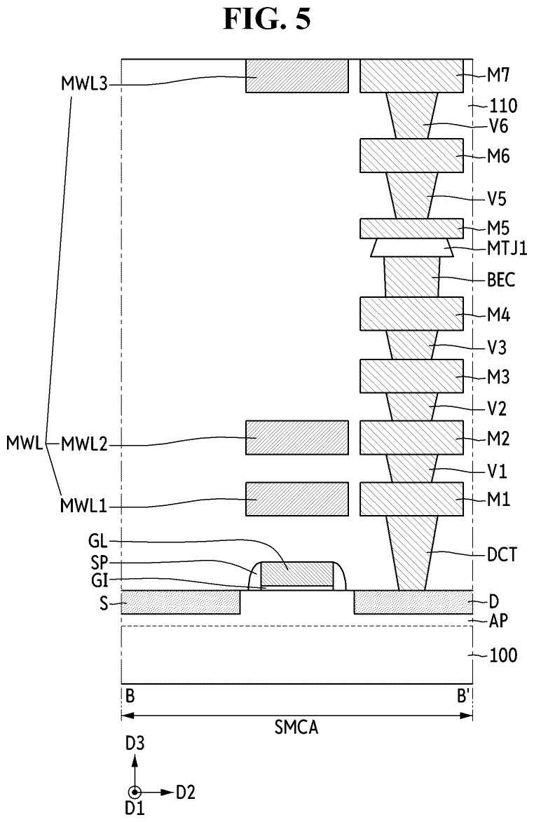

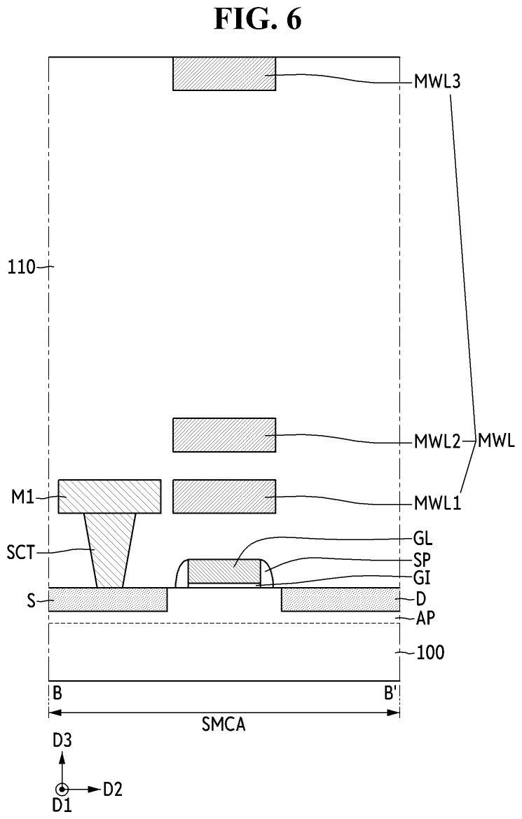

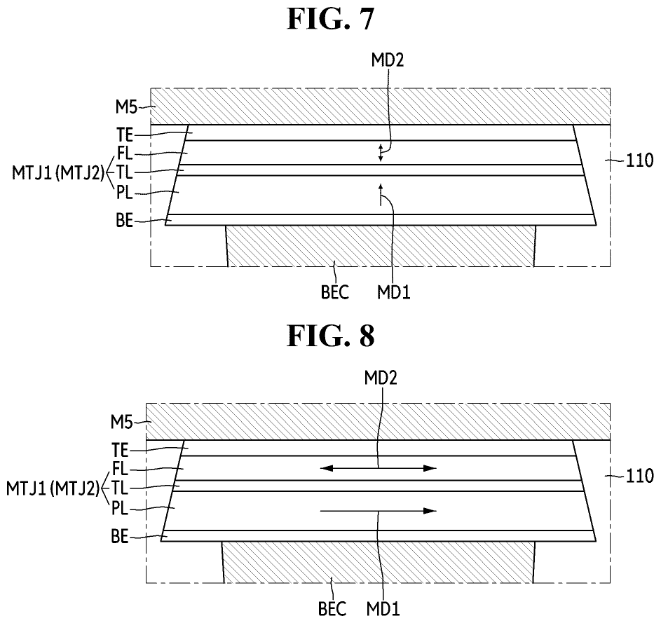

FIG. 3 is an example layout diagram for illustrating a magnetic memory device according to some embodiments. FIG. 4 is a cross-sectional view cut along A-A′ in FIG. 3. FIG. 5 is a cross-sectional view cut along B-B′ in FIG. 3. FIG. 6 is a cross-sectional view cut along C-C′ in FIG. 3. FIG. 7 and FIG. 8 are example cross-sectional views for illustrating first and second magnetic tunnel junction elements of FIGS. 4 to 6.

Referring to FIGS. 3 to 8, a magnetic memory device according to some embodiments includes a sub-memory cell array SMCA and a dummy area DR. In some embodiments, there may be a plurality of sub-memory cell arrays SMCA and a plurality of dummy areas DR.

The sub-memory cell array SMCA may include a plurality of memory cells (MC in FIG. 2). In the sub-memory cell array SMCA, the memory cell (MC in FIG. 2) connected to the bit-line (BL in FIG. 2) and the word-line (WL in FIG. 2) and including a first magnetic tunnel junction element MTJ1 may be formed. In one example, the sub-memory cell array SMCA may be defined on a write I/O basis. However, embodiments of the present disclosure are not limited thereto, and the sub-memory cell array SMCA may be defined in various manners.

A gate line GL may extend across the sub-memory cell array SMCA and the dummy area DR. The gate line GL may extend in an elongate manner in a first direction D1. Gate lines GL may be spaced apart from each other in a second direction D2. The gate line GL may be provided as the gate electrode of the select transistor ST in FIG. 2. The gate line GL may be referred to as a word-line.

The sub-memory cell arrays SMCA may be connected to each other via the gate lines GL. Each gate line GL may be connected to the memory cells located in the same row as a row of each gate line GL. For example, the gate line GL located in one row may be connected to the memory cells MC located in one row.

In this regard, the row may be defined based on the first direction D1 and a column may be defined based on the second direction D2. The first direction D1, the second direction D2, and a third direction D3 may intersect each other. The first direction D1 and the second direction D2 may be parallel to an upper surface of the substrate 100, and the third direction D3 may be perpendicular to the upper surface of the substrate 100.

A metal word-line MWL may extend across the sub-memory cell array SMCA and dummy area DR. The metal word-line MWL may extend in an elongate manner in the first direction D1. The metal word-lines MWL may be spaced apart from each other in the second direction D2.

The metal word-line MWL may be formed on the gate line GL. The metal word-line MWL may overlap at least a portion of the gate line GL in the third direction D3.

A second magnetic tunnel junction element MTJ2 and a word-line contact GCT are formed in the dummy area DR. The metal word-line MWL is electrically connected to the second magnetic tunnel junction element MTJ2 and the word-line contact GCT in the dummy area DR. The metal word-line MWL is electrically connected to the gate line GL via the second magnetic tunnel junction element MTJ2 and the word-line contact GCT in the dummy area DR. The metal word-line MWL and the gate line GL may constitute a strap structure. Accordingly, because an electrical signal is applied not only via the gate line GL but also via the metal word-line MWL, a resistance of the word-line may be reduced, thereby improving the operating speed of the magnetic memory device.

The dummy area DR may be formed, for example, between neighboring sub-memory cell arrays SMCA.

The magnetic memory device according to some embodiments may include a substrate 100, an active area ACT, an active pattern AP, the gate line GL, an interlayer insulating film 110, a drain contact DCT, a source contact SCT, the word-line contact GCT, the first magnetic tunnel junction element MTJ1, the second magnetic tunnel junction element MTJ2, the metal word-line MWL, first to seventh metal layers M1 to M7, first to sixth vias V1 to V6, and a lower electrode contact BEC.

The substrate 100 may be, for example, a silicon substrate, a gallium arsenide substrate, a silicon germanium substrate, a ceramic substrate, a quartz substrate, or a glass substrate for a display, or may be a SOI (Semiconductor On Insulator) substrate. However, embodiments of the present disclosure are not limited thereto.

The active area ACT may be formed in the sub-memory cell array SMCA. The substrate 100 may include the active area ACT. For example, the active area ACT may be an area in which a channel area of a transistor (for example, the cell transistor ST in FIG. 2) is formed. In other embodiments, the active area ACT may be an area in which a fin-shaped pattern a nanosheet used as a channel area of a transistor is formed. The active area ACT may be defined by a deep trench DT. A portion of the active area ACT that intersects the gate line GL may be provided as the channel area of the select transistor ST in FIG. 2.

The active pattern AP may be formed in the active area ACT. The active pattern AP may protrude from the substrate 100 in the active area ACT. The active pattern AP may extend in an elongate manner along the second direction D2 while being disposed on the substrate 100. The active patterns AP may be spaced apart from each other in the first direction D1. The number of active patterns AP formed in the active area ACT may vary.

The active pattern AP may be a multi-channel active pattern. In a semiconductor device according to some embodiments, the active pattern AP may be, for example, a fin-shaped pattern. The active pattern AP may be used as the channel area of each transistor.

The active pattern AP may be a portion of the substrate 100 or may include an epitaxial layer grown from the substrate 100. The active pattern AP may include, for example, silicon or germanium as an elemental semiconductor material. In other embodiments, the active pattern AP may include a compound semiconductor, for example, a group IV-IV compound semiconductor or a group III-V compound semiconductor.

A field insulating film 105 may be formed on the substrate 100. The field insulating film 105 may be disposed across the active area ACT and the dummy area DR. The field insulating film 105 may at least partially fill the deep trench DT. The field insulating film 105 may be on and at least partially cover a sidewall of the active pattern AP. The active pattern AP may protrude above an upper surface of the field insulating film 105 in the D3 direction. The field insulating film 105 may include, for example, an oxide film, a nitride film, an oxynitride film, or a combination thereof.

The gate line GL may be disposed on the substrate 100. The gate line GL may be disposed on the field insulating film 105 and the active pattern AP.

The gate line GL may include at least one of a semiconductor material doped with a dopant, a metal, a conductive metal nitride, and/or a metal-semiconductor compound. The gate line GL may be embodied as a single film or a stack of multi-films. For example, the gate line GL may include a work function control film that controls a work function, and a filling conductive film that at least partially fills a space defined by the work function control film.

A gate dielectric film GI may be disposed between the gate line GL and the substrate 100. For example, the gate dielectric film GI may include at least one of silicon oxide and/or a high dielectric constant material.

A gate spacer SP may be disposed on a sidewall of the gate line GL. For example, the gate spacer SP may include at least one of silicon oxide, silicon nitride, and/or silicon oxynitride.

The active pattern AP may include a source pattern S and a drain pattern D. The source pattern S may be disposed on one side of the gate line GL and the drain pattern D may be disposed on the other side of the gate line GL. The source pattern S and the drain pattern D may be insulated from the gate line GL via the gate spacer SP and/or the gate dielectric film GI.

Each of the source pattern S and the drain pattern D may include an epitaxial layer doped with impurities. Each of the source pattern S and the drain pattern D may contain N-type or P-type impurities.

The interlayer insulating film 110 may be formed on the substrate 100. The interlayer insulating film 110 may be on and at least partially cover the substrate 100, the gate line GL, and the gate spacer SP. The drain contact DCT, the source contact SCT, the word-line contact GCT, the first magnetic tunnel junction element MTJ1, the second magnetic tunnel junction element MTJ2, the metal word-line MWL, the first to seventh metal layers M1 to M7, the first to sixth vias V1 to V6, and the lower electrode contact BEC may be formed in the interlayer insulating film 110. The interlayer insulating film 110 may include at least one of a silicon oxide film, a silicon nitride film, a silicon oxynitride film, and/or a low dielectric constant film.

The first magnetic tunnel junction element MTJ1, the drain contact DCT, and the source contact SCT may be formed in the sub-memory cell array SMCA. In the sub-memory cell array SMCA, the drain pattern D may be electrically connected to the first magnetic tunnel junction element MTJ1. In the sub-memory cell array SMCA, the drain contact DCT, the first metal layer M1, the first via V1, the second metal layer M2, the second via V2, the third metal layer M3, the third via V3, the fourth metal layer M4, the lower electrode contact BEC, and the first magnetic tunnel junction element MTJ1 may be sequentially stacked on the drain pattern D. The drain pattern D may be electrically connected to the first metal layer M1 via the drain contact DCT. The second metal layer M2 may be electrically connected to the first metal layer M1 via the first via V1. The third metal layer M3 may be electrically connected to the fourth metal layer M4 via the third via V3. The fourth metal layer M4 may be electrically connected to the first magnetic tunnel junction element MTJ1 via the lower electrode contact BEC. The fifth metal layer M5, the fifth via V5, the sixth metal layer M6, the sixth via V6, and the seventh metal layer M7 may be stacked on the first magnetic tunnel junction element MTJ1 in this order. The lower electrode contact BEC may be electrically connected to the fifth metal layer M5 via the first magnetic tunnel junction element MTJ1. The fifth metal layer M5 may be electrically connected to the sixth metal layer M6 via the fifth via V5. The fifth metal layer M5 may be provided as the bit-line BL in FIG. 2 in one example. The sixth metal layer M6 may be electrically connected to the seventh metal layer M7 via the sixth via V6.

In the sub-memory cell array SMCA, the source pattern S may be electrically connected to the source line SL. In the sub-memory cell array SMCA, the source contact SCT and the source line SL may be sequentially stacked on the source pattern S. The source pattern S may be electrically connected to the source line SL via the source contact SCT. For example, the source line SL may be positioned at the same vertical level (level in the D3 direction) as a vertical level the first metal layer M1 based on the substrate 100.

The metal word-line MWL may be disposed on the substrate 100. The metal word-line MWL may be disposed on the field insulating film 105 and the active pattern AP.

The word-line contact GCT and the second magnetic tunnel junction element MTJ2 are formed in the dummy area DR. In the dummy area DR, the metal word-line MWL is electrically connected to the gate line GL via the word-line contact GCT and the second magnetic tunnel junction element MTJ2.

In some embodiments, the metal word-line MWL may include a first metal word-line MWL1, a second metal word-line MWL2, and a third metal word-line MWL3.

The third metal word-line MWL3 may be disposed at a higher vertical level (level in the D3 direction) than a vertical level of each of the first and second magnetic tunnel junction elements MTJ1 and MTJ2. The first and second metal word-lines MWL1 and MWL2 may be positioned at a lower vertical level (level in the D3 direction) than a vertical level of each of the first and second magnetic tunnel junction elements MTJ1 and MTJ2. The third metal word-line MWL3 may be disposed at a higher vertical level (level in the D3 direction) than a vertical level of the bit-line (e.g., the fifth metal layer M5). The first and second metal word-lines MWL1 and MWL2 may be positioned at a lower vertical level (level in the D3 direction) than a vertical level of the bit-line (e.g., the fifth metal layer M5).

For example, the first metal word-line MWL1 may be positioned at the same vertical level (level in the D3 direction) as a vertical level of the second metal layer M2 based on the substrate 100. The second metal word-line MWL2 may be positioned at the same vertical level (level in the D3 direction) as a vertical level of the third metal layer M3 based on the substrate 100. The third metal word-line MWL3 may be positioned at the same vertical level (level in the D3 direction) as a vertical level of the seventh metal layer M7 based on the substrate 100.

In the dummy area DR, the gate line GL is electrically connected to the metal word-line MWL. In the sub-memory cell array SMCA, the gate line GL and the metal word-line MWL may not be electrically connected to each other.

In the dummy area DR, the word-line contact GCT, the first metal layer M1, the first via V1, the first metal word-line MWL1, the second via V2, the second metal word-line MWL2, the third via V3, the fourth metal layer M4, the lower electrode contact BEC, the second magnetic tunnel junction element MTJ2, the fifth metal layer M5, the fifth via V5, the sixth metal layer M6, the sixth via V6, and the third metal word-line MWL3 may be sequentially stacked on the gate line GL. The gate line GL may be electrically connected to the first metal layer M1 via a word-line contact GCT. The first metal word-line layer MWL1 may be electrically connected to the second metal word-line MWL2 via the first via V1. The second metal word-line MWL2 may be electrically connected to the fourth metal layer M4 via the third via V3. The fourth metal layer M4 may be electrically connected to the second magnetic tunnel junction element MTJ2 via the lower electrode contact BEC. The lower electrode contact BEC may be electrically connected to the fifth metal layer M5 via the second magnetic tunnel junction element MTJ2. The fifth metal layer M5 may be electrically connected to the sixth metal layer M6 via the fifth via V5. The sixth metal layer M6 may be electrically connected to the third metal word-line MWL3 via the sixth via V6.

For example, the first metal word-line MWL1 may be positioned at the same vertical level (level in the D3 direction) as a vertical level of the second metal layer M2 based on the substrate 100. The second metal word-line MWL2 may be positioned at the same vertical level (level in the D3 direction) as a vertical level of the third metal layer M3 based on the substrate 100. The third metal word-line MWL3 may be positioned at the same vertical level (level in the D3 direction) as a vertical level of the seventh metal layer M7 based on the substrate 100. The second magnetic tunnel junction element MTJ2 may be positioned at the same vertical level (level in the D3 direction) as a vertical level of the first magnetic tunnel junction element MTJ1 based on the substrate 100.

Each of the drain contact DCT, the source contact SCT, and the word-line contact GCT may include a conductive material. Each of the metal word-line MWL, the first to seventh metal layers M1 to M7, and the first to sixth vias V1 to V6 may include metal (e.g., copper).

The second magnetic tunnel junction element MTJ2 may have the same structure as that of the first magnetic tunnel junction element MTJ1. In some embodiments, the second magnetic tunnel junction element MTJ2 may have the same size as that of the first magnetic tunnel junction element MTJ1.

Referring to FIG. 7 and FIG. 8, each of the first and second magnetic tunnel junction elements MTJ1 and MTJ2 may be disposed between the lower electrode contact BEC and the fifth metal layer M5. Each of the first and second magnetic tunnel junction elements MTJ1 and MTJ2 may be electrically connected to the lower electrode contact BEC and the fifth metal layer M5.

In some embodiments, a lower electrode BE may be further disposed between each of the first and second magnetic tunnel junction elements MTJ1 and MTJ2 and the lower electrode contact BEC. An upper electrode TE may be further disposed between each of the first and second magnetic tunnel junction elements MTJ1 and MTJ2 and the fifth metal layer M5.

The lower electrode BE may include, for example, a conductive metal nitride (e.g., titanium nitride or tantalum nitride). The upper electrode TE may include at least one of a metal (e.g., Ta, W, Ru, Ir, etc.) and/or a conductive metal nitride (e.g., TiN). The lower electrode contact BEC may include at least one of a doped semiconductor material (e.g., doped silicon), a metal (e.g., tungsten, titanium, and/or tantalum), a metal-semiconductor compound (e.g., metal silicide), and/or a conductive metal nitride (e.g., titanium nitride, tantalum nitride, and/or tungsten nitride).

Each of the first and second magnetic tunnel junction elements MTJ1 and MTJ2 may include a first magnetic pattern PL, a tunnel barrier pattern TL, and a second magnetic pattern FL. The tunnel barrier pattern TL may be interposed between the first magnetic pattern PL and the second magnetic pattern FL.

One of the first magnetic pattern PL and the second magnetic pattern FL may be a reference layer having a fixed magnetization direction MD1 regardless of an external magnetic field. The other of the first magnetic pattern PL and the second magnetic pattern FL may be a free layer having a variable magnetization direction MD2 that may be switched between two stable magnetization directions. For example, the first magnetic pattern PL may be the reference layer with the fixed magnetization direction MD1, and the second magnetic pattern FL may be the free layer with the variable magnetization direction MD2. In another example, unlike what is shown, the first magnetic pattern PL may be the free layer and the second magnetic pattern FL may be the reference layer.

Referring to FIG. 7, in some embodiments, each of the first magnetic pattern PL and the second magnetic pattern FL may have perpendicular magnetic anisotropy (PMA). Each of the first magnetic pattern PL and the second magnetic pattern FL may have a magnetization easy axis in a perpendicular direction (perpendicular to the upper surface of the substrate 100) (the third direction D3 in FIGS. 3 to 6).

Each of the first magnetic pattern PL and the second magnetic pattern FL may include at least one of a perpendicular magnetic material (e.g., CoFeTb, CoFeGd, CoFeDy), a perpendicular magnetic material with an L1₀ structure, and CoPt having a HCP (Hexagonal Close Packed) lattice structure, and/or a perpendicular magnetic structure. The perpendicular magnetic material having the L1₀ structure may include, for example, FePt of the L1₀ structure, FePd of the L1₀ structure, CoPd of the L1₀ structure, or CoPt of the L1₀ structure. The perpendicular magnetic structure may include magnetic layers and non-magnetic layers alternatingly and repeatedly stacked on top of each other. For example, the perpendicular magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ or (CoCr/Pd)ₙ where n is the number of stacks, etc.

Referring to FIG. 8, in some embodiments, each of the first magnetic pattern PL and the second magnetic pattern FL may have in-plane magnetic anisotropy (IMA). Each of the first magnetic pattern PL and the second magnetic pattern FL may have a magnetization easy axis in a horizontal direction (a direction parallel to the upper surface of the substrate 100).

Each of the first magnetic pattern PL and the second magnetic pattern FL having the in-plane magnetic anisotropy (IMA) may include a ferromagnetic material. In some embodiments, one acting as the reference layer among the first magnetic pattern PL and the second magnetic pattern FL may further include an antiferromagnetic material for fixing the magnetization direction MD1 of the ferromagnetic material. For example, the ferromagnetic material of the reference layer may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and/or Y3Fe5O12. For example, the antiferromagnetic material of the reference layer may include at least one material selected from at least one of PtMn, IrMn, MnO, MnS, MnTe, MnF2, FeCl2, FeO, CoCl2, CoO, NiCl2, NiO and Cr, or a precious metal. The precious metal may include ruthenium (Ru), rhodium (Rh), palladium (Pd), osmium (Os), iridium (Ir), platinum (Pt), gold (Au), and/or silver (Ag). For example, the ferromagnetic material of the free layer may include at least one of FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and/or Y3Fe5O12. The magnetic pattern acting as the free layer may be composed of a plurality of layers.

Referring again to FIG. 7 and FIG. 8, the tunnel barrier pattern TL may include at least one material selected from, for example, oxides of magnesium (Mg), titanium (Ti), aluminum (Al), magnesium-zinc (MgZn), and/or magnesium-boron (MgB) and nitrides of titanium (Ti) and/or vanadium (V).

Each of the first and second magnetic tunnel junction elements MTJ1 and MTJ2 may store data in each memory cell MC based on an electrical resistance varying based on the magnetization direction MD1 of the first magnetic pattern PL and the magnetization direction MD2 of the second magnetic pattern FL.

For example, when the magnetization direction MD1 of the first magnetic pattern PL and the magnetization direction MD2 of the second magnetic pattern FL are parallel to each other, each of the first and second magnetic tunnel junction elements MTJ1 and MTJ2 may have a low resistance value, such that data 0 may be stored. Conversely, when the magnetization direction MD1 of the first magnetic pattern PL and the magnetization direction MD2 of the second magnetic pattern FL are anti-parallel to each other, each of the first and second magnetic tunnel junction elements MTJ1 and MTJ2 may have a high resistance value, such that data 1 may be stored. In another example, when the magnetization direction MD1 of the first magnetic pattern PL and the magnetization direction MD2 of the second magnetic pattern FL are parallel to each other, the first magnetic tunnel junction element MTJ1 may store data 1 therein. When the magnetization direction MD1 of the first magnetic pattern PL and the magnetization direction MD2 of the second magnetic pattern FL are anti-parallel to each other, the first magnetic tunnel junction element MTJ1 may store data 0 therein.

In the magnetic memory device according to some embodiments, the resistance of the second magnetic tunnel junction element MTJ2 electrically connecting the metal word-line MWL and the gate line GL to each other in the dummy area DR may be reduced using various schemes.

In the magnetic memory device according to some embodiments, an additional process using a magnetic field may be performed on the second magnetic tunnel junction element MTJ2. The magnetization direction MD1 of the first magnetic pattern PL of the second magnetic tunnel junction element MTJ2 and the magnetization direction MD2 of the second magnetic pattern FL may be parallel to each other. Accordingly, the second magnetic tunnel junction element MTJ2 may have a low resistance value. Therefore, the resistance of the magnetic tunnel junction element MTJ2 connected to the metal word-line MWL may be reduced, so that the resistance of the word-line may be reduced, and thus, the operation speed of the magnetic memory device may be improved.

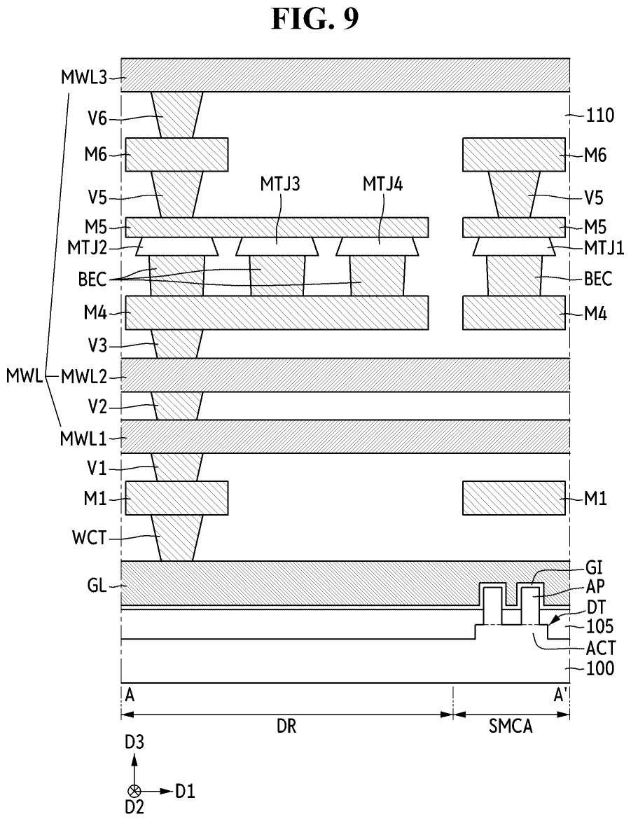

FIGS. 9 to 14 are diagrams for illustrating a magnetic memory device according to some embodiments. For reference, FIGS. 8 to 14 are cross-sectional views taken along A-A′ in FIG. 3. For convenience of description, contents duplicate with those described above using FIGS. 1 to 8 are briefly described or descriptions thereof are omitted.

Referring to FIG. 9, in the magnetic memory device according to some embodiments, in the dummy area DR, the metal word-line MWL may be electrically connected to the gate line GL via the word-line contact GCT and a plurality of magnetic tunnel junction elements MTJ2, MTJ3, and MTJ4.

For example, in the dummy area DR, the second to fourth magnetic tunnel junction elements MTJ2, MTJ3, and MTJ4 may be disposed between the fourth metal layer M4 and the fifth metal layer M5 and may be arranged to be spaced apart from each other. The lower electrode contact BEC may be disposed between each of the second to fourth magnetic tunnel junction elements MTJ2, MTJ3, MTJ4 and the fourth metal layer M4. The fourth metal layer M4 may be electrically connected to each of the second to fourth magnetic tunnel junction elements MTJ2, MTJ3, and MTJ4 via each lower electrode contact BEC. Each of the lower electrode contacts BEC may be electrically connected to the fifth metal layer M5 via each of the second to fourth magnetic tunnel junction elements MTJ2, MTJ3, and MTJ4.

Each of the second to fourth magnetic tunnel junction elements MTJ2, MTJ3, and MTJ4 may have the same structure as the structure of the first magnetic tunnel junction element MTJ1. In some embodiments, a size of each of the second to fourth magnetic tunnel junction elements MTJ2, MTJ3, and MTJ4 may be equal to that of the first magnetic tunnel junction element MTJ1.

In the dummy area DR, the number of magnetic tunnel junction elements spaced apart from each other (connected in parallel with each other) and disposed between the fourth metal layer M4 and the fifth metal layer M5 is not limited thereto but may vary.

In the dummy area DR, the gate line GL may be electrically connected to the metal word-line MWL via the word-line contact GCT and the second to fourth magnetic tunnel junction elements MTJ2, MTJ3, and MTJ4. In this regard, in the dummy area DR, the second to fourth magnetic tunnel junction elements MTJ2, MTJ3, and MTJ4 may have first and second magnetic patterns PL and FL that are parallel to each other. Therefore, a resistance of each of the magnetic tunnel junction elements MTJ2, MTJ3, and MTJ4 connected to the metal word-line MWL may be reduced, so that the resistance of the word-line may be reduced, and thus, the operation speed of the magnetic memory device may be improved.

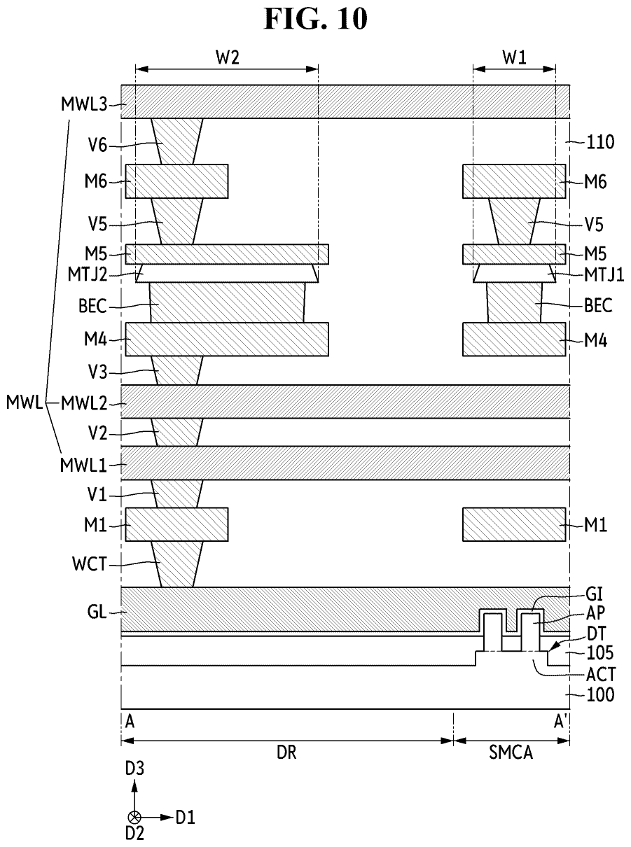

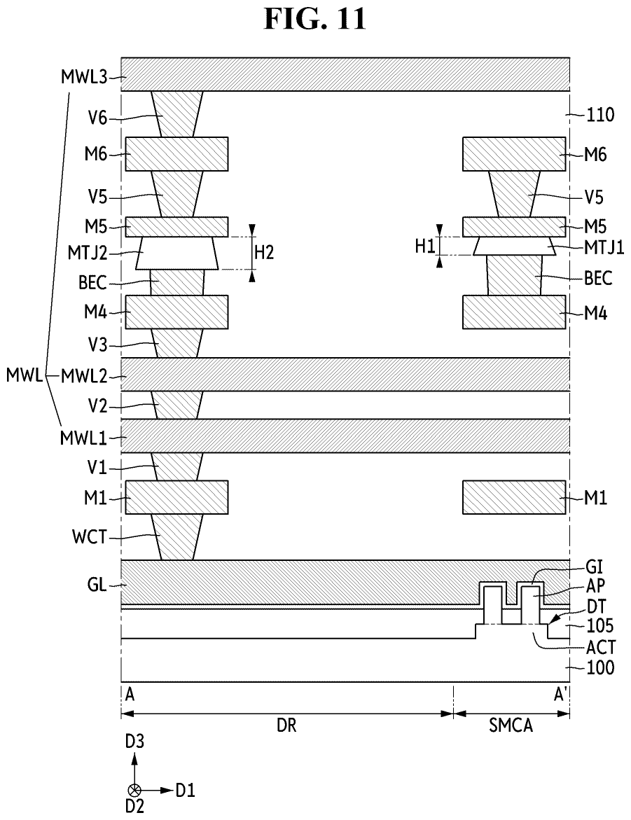

Referring to FIG. 10 and FIG. 11, in the magnetic memory device according to some embodiments, the size of the second magnetic tunnel junction element MTJ2 may be larger than the size of the first magnetic tunnel junction element MTJ1.

Referring to FIG. 10, in some embodiments, a maximum width W2 of the second magnetic tunnel junction element MTT2 may be greater than a maximum width W1 of the first magnetic tunnel junction element MTJ1. In this regard, the width may be defined based on a direction (for example, the first direction D1 or the second direction D2) parallel to the upper surface of the substrate.

Referring to FIG. 11, in some embodiments, a height H2 of the second magnetic tunnel junction element MTJ2 may be greater than a height H1 of the first magnetic tunnel junction element MTJ1. In this regard, the height may be defined based on a direction (for example, the third direction D3) perpendicular to the upper surface of the substrate.

Accordingly, the resistance value of the second magnetic tunnel junction element MTJ2 may be less than the resistance value of the first magnetic tunnel junction element MTJ1. Therefore, the resistance of the magnetic tunnel junction element MTJ2 connected to the metal word-line MWL may be reduced, so that the resistance of the word-line may be reduced, and thus, the operation speed of the magnetic memory device may be improved.

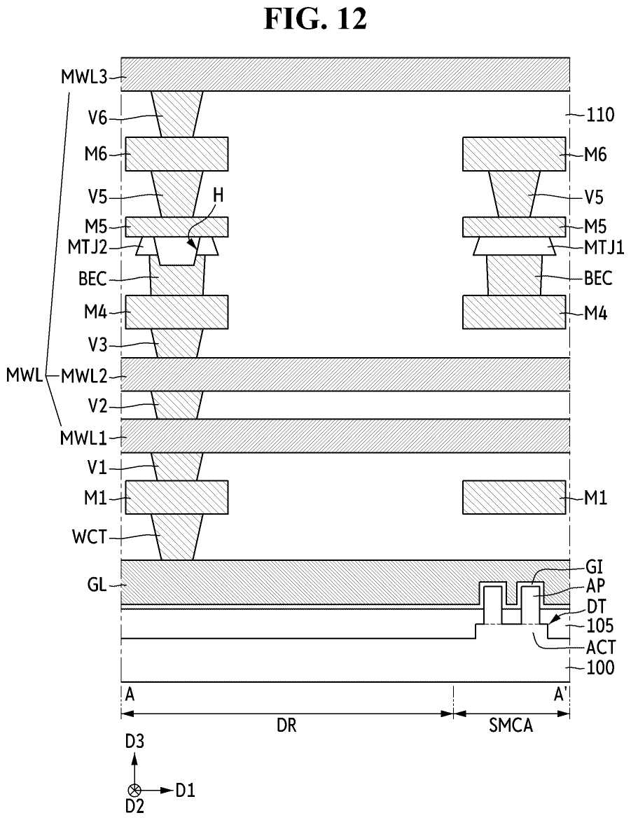

Referring to FIG. 12, in the magnetic memory device according to some embodiments, the second magnetic tunnel junction element MTJ2 may be in a short-circuited state. Accordingly, the resistance value of the second magnetic tunnel junction element MTJ2 may be less than the resistance value of the first magnetic tunnel junction element MTJ1. Therefore, the resistance of the magnetic tunnel junction element MTJ2 connected to the metal word-line MWL may be reduced, so that the resistance of the word-line may be reduced, and thus, the operation speed of the magnetic memory device may be improved.

For example, the second magnetic tunnel junction element MTJ2 may include a through-hole H extending therethrough. As a result, the tunnel barrier pattern (TL in FIG. 7 and FIG. 8) of the second magnetic tunnel junction element MTJ2 may be destroyed, such that the second magnetic tunnel junction element MTJ2 may be brought into the short-circuited state. For example, the through-hole H may be formed in a via forming process. For example, the through-hole H may be at least partially filled with a conductive material, and an electrical short circuit between the first and second magnetic patterns (PL and FL in FIG. 7 and FIG. 8) of the second magnetic tunnel junction element MTJ2 may occur.

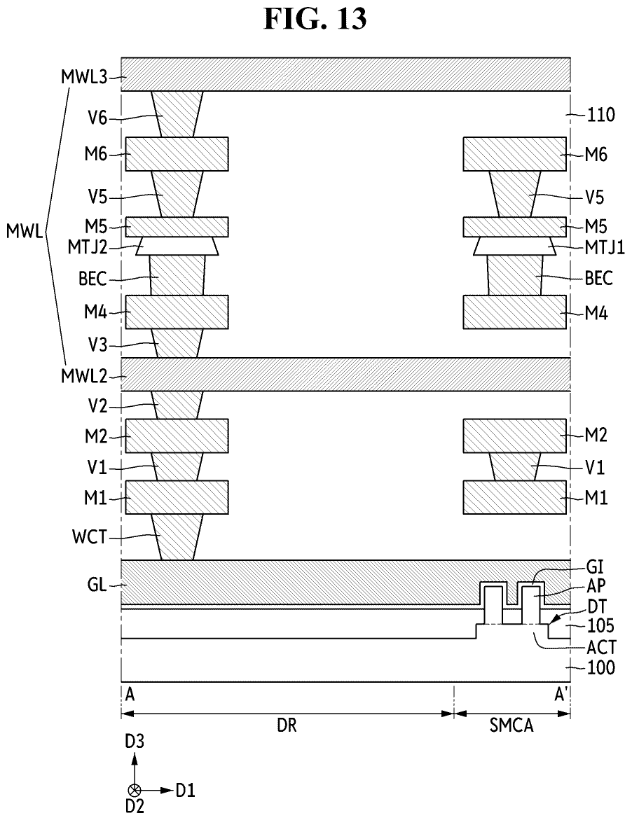

Referring to FIG. 13, in a magnetic memory device according to some embodiments, the metal word-line MWL may include the second metal word-line MWL2 and the third metal word-line MWL3.

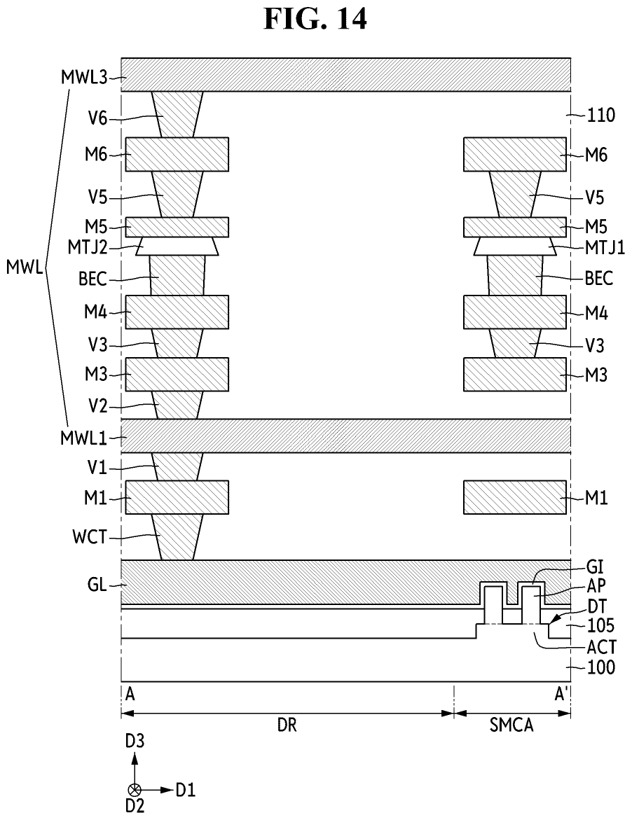

Referring to FIG. 14, in a magnetic memory device according to some embodiments, the metal word-line MWL may include the first metal word-line MWL1 and the third metal word-line MWL3.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A magnetic memory device comprising:
a memory cell connected to a bit-line and a word-line and including a first magnetic tunnel junction element; and
a second magnetic tunnel junction element and a metal word-line on the word-line, and electrically connected to the word-line.

2. The magnetic memory device of claim 1, wherein a width of the second magnetic tunnel junction element is different from a width of the first magnetic tunnel junction element in an elongate direction of the word-line and the metal word-line.

3. The magnetic memory device of claim 1, wherein a width of the second magnetic tunnel junction element is greater than a width of the first magnetic tunnel junction element in an elongate direction of the word-line and the metal word-line.

4. The magnetic memory device of claim 1, wherein the word-line and the metal word-line are spaced apart in a first direction, and
wherein a height of the second magnetic tunnel junction element is different from a height of the first magnetic tunnel junction element in the first direction.

5. The magnetic memory device of claim 1, wherein the word-line and the metal word-line are spaced apart in a first direction, and
wherein a height of the second magnetic tunnel junction element is greater than a height of the first magnetic tunnel junction element in the first direction.

6. The magnetic memory device of claim 1, further comprising a third magnetic tunnel junction element on the word-line and connected in parallel with the second magnetic tunnel junction element, and
wherein the third magnetic tunnel junction element is electrically connected to the metal word-line and the word-line.

7. The magnetic memory device of claim 1, wherein the second magnetic tunnel junction element further includes a through-hole extending therethrough.

8. The magnetic memory device of claim 1, wherein the second magnetic tunnel junction element includes a first magnetic pattern, a second magnetic pattern, and a tunnel barrier pattern between the first magnetic pattern and the second magnetic pattern, and
wherein a magnetization direction of the first magnetic pattern and a magnetization direction of the second magnetic pattern are parallel to each other.

9. The magnetic memory device of claim 1, wherein the word-line and the metal word-line are spaced apart in a first direction,
wherein the metal word-line includes a first metal word-line and a second metal word-line,
wherein a vertical level in the first direction from the word-line of the first metal word-line is lower than a vertical level in the first direction from the word-line of the second magnetic tunnel junction element, and
wherein a vertical level of the second metal word-line in the first direction from the word-line is higher than the vertical level in the first direction from the word-line of the second magnetic tunnel junction element.

10. The magnetic memory device of claim 9, wherein the vertical level of the second metal word-line in the first direction from the word-line is higher than a vertical level of the bit-line.

11. The magnetic memory device of claim 9, wherein the metal word-line further includes a third metal word-line, and
wherein a vertical level in the first direction from the word-line of the third metal word-line is lower than the vertical level in the first direction from the word-line of the second metal word-line.

12. A magnetic memory device comprising:
a substrate including a sub-memory cell array and a dummy area;
a gate line on the substrate;
a first magnetic tunnel junction element on a portion of the gate line on the sub-memory cell array;
a second magnetic tunnel junction element on a portion of the gate line on the dummy area; and
a metal word-line on the gate line,
wherein the portion of the gate line on the dummy area is electrically connected to the second magnetic tunnel junction element and the metal word-line.

13. The magnetic memory device of claim 12, further comprising a third magnetic tunnel junction element on the dummy area of the substrate and spaced apart from the second magnetic tunnel junction element, and
wherein on the dummy area, the word-line is electrically connected to the third magnetic tunnel junction element.

14. The magnetic memory device of claim 12, wherein a width of the second magnetic tunnel junction element is different from a width of the first magnetic tunnel junction element in an elongate direction of the gate line and the metal word-line.

15. The magnetic memory device of claim 12, wherein the second magnetic tunnel junction element is configured in a short-circuited state.

16. The magnetic memory device of claim 12, wherein the second magnetic tunnel junction element includes a first magnetic pattern, a second magnetic pattern, and a tunnel barrier pattern between the first magnetic pattern and the second magnetic pattern,
wherein a magnetization direction of the first magnetic pattern and a magnetization direction of the second magnetic pattern are parallel to each other.

17. The magnetic memory device of claim 12, wherein the gate line and the metal word-line are spaced apart in a first direction,
wherein the metal word-line includes a first metal word-line and a second metal word-line,
wherein a vertical level in the first direction from the substrate of the first metal word-line is higher than a vertical level in the first direction from the substrate of the second magnetic tunnel junction element, and
wherein a vertical level in the first direction from the substrate of a second metal word-line disposed is lower than the vertical level in the first direction from the substrate of the second magnetic tunnel junction element.

18. A magnetic memory device comprising:
a substrate including a sub-memory cell array and a dummy area;
a bit-line and a word-line on the substrate;
a memory cell on the sub-memory cell array of the substrate, wherein the memory cell includes a first memory element connected to the bit-line, and a select transistor connected to the first memory element and having a gate connected to the word-line;
a metal word-line on the word-line; and
a second memory element on the dummy area of the substrate,
wherein the word-line on the dummy area is electrically connected to the second memory element and the metal word-line.

19. The magnetic memory device of claim 18, wherein each of the first memory element and the second memory element includes a magnetic tunnel junction element.

20. The magnetic memory device of claim 18, wherein the word-line and the metal word-line are spaced apart in a first direction,
wherein the metal word-line includes a first metal word-line and a second metal word-line,
wherein a vertical level in the first direction from the substrate of the first metal word-line is lower than a vertical level in the first direction from the substrate of the bit-line, and
wherein a vertical level in the first direction from the substrate of a second metal word-line disposed is higher than the vertical level in the first direction from the substrate of the bit-line.
